(19) United States
(12) Patent Application Publication
(10) Pub. No.: US 2025/0334611 A1
(43) Pub. Date: Oct. 30, 2025

(54) PROBING HEAD

(71) Applicant: TSE CO., LTD., Cheonan-si (KR)

(72) Inventors: Young Hun JU, Cheonan-si (KR); Yoon Young JIN, Cheonan-si (KR); Sin Jae KIM, Cheonan-si (KR)

(73) Assignee: TSE CO., LTD., Cheonan-si (KR)

(21) Appl. No.: 19/186,832

(22) Filed: Apr. 23, 2025

(30) Foreign Application Priority Data
Apr. 30, 2024 (KR) 10-2024-0057992
Jul. 30, 2024 (KR) 10-2024-0100886

(51) Int. Cl. G01R 1/073; G01R 1/067

(52) U.S. Cl. CPC G01R 1/07378; G01R 1/06716; G01R 1/07342

(57) ABSTRACT

Disclosed is a probing head including a probe located in the form of a pin from an inspection target substrate toward a space conversion unit, the probe having a displacement portion and an elastic portion located near the space conversion unit and the inspection target substrate, respectively, and a lower plate and an upper plate sequentially located in a longitudinal direction of the probe, the lower plate and the upper plate being configured to surround the displacement portion, wherein the probe has an anchor protruding from the probe at the displacement portion.

### CROSS-REFERENCE TO RELATED APPLICATIONS

This application claims priority to Korean Patent Application No. 10-2024-0057992, filed on Apr. 30, 2024, and Korean Patent Application No. 10-2024-0100886, filed on Jul. 30, 2024, the entire contents of which are herein incorporated by reference.

### BACKGROUND OF THE INVENTION

### 1. Field of the Invention

The present invention relates to a probing head configured such that, when an inspection target substrate is located under a space conversion unit of a probe card, the probing head is located between the space conversion unit and the inspection target substrate so as to be in contact with an electrical pad of the space conversion unit and a substrate pad of the inspection target substrate.

### 2. Description of the Related Art

In general, an electrical die sorting (EDS) process is performed between a semiconductor front-end process and a semiconductor back-end process. Here, the semiconductor front-end process is performed to repeatedly form semiconductor chips on an inspection target substrate. The semiconductor back-end process is performed to cut the inspection target substrate into semiconductor chips and to package the semiconductor chips.

In addition, the EDS process is performed to check the electrical operation of the semiconductor chips on the inspection target substrate. That is, the EDS process is the performed to inspect the electrical operation of t semiconductor chips through a probe card in the state in which a probe card and the inspection target substrate are mounted on an electrical test device.

Specifically, conventionally, as shown in FIG. 1, a probe card 540 has a test head 100 and a space conversion unit 530, which are sequentially stacked. The test head 100 includes probes 50 and lower and upper plates 70 and 90 configured to surround each individual probe 50.

During the EDS process, the test head 100 is mounted on an electrical test device (not shown) through the probe card 540 along with the space conversion unit 530 so as to be in contact with the space conversion unit 530 and an inspection target substrate 570. The test head 100 has a plurality of probes 50 extending through lower guide holes 65 of the lower plate 70 and upper guide holes 85 of the upper plate 90 in the lower and upper plates 70 and 90.

In FIG. 1, the probe 50 has a probing lower tip (not shown), an elastic portion 10, a displacement portion 30, and a probing upper tip 40 sequentially provided in a longitudinal direction of the probe 50. The elastic portion 10 has an anchor 5 formed on each individual probe 50 between two neighboring probes 50.

The anchor 5 prevents separation of the probe from the lower plate 70 and the upper plate 90 upon maintenance of the probe card 540 during the lifespan of the probe card 540. The displacement portion 30 has two variable holes 25 formed in each individual probe 50 and maintains the initial shape thereof through the two variable holes 25 during movement of the elastic portion 10.

Although not shown, the probe 50 comes into contact with a substrate pad 565 of the inspection target substrate 570 through the probing lower tip, comes into contact with an electrical pad 525 of the space conversion unit 530 through the probing upper tip 40, and is pressed through the space conversion unit 530 and the inspection target substrate 570 to cause the buckling of the elastic portion 10.

In this case, the substrate pad 565 is located at a semiconductor chip (not shown) on the inspection target substrate 570. During the buckling of the elastic portion 10 of the probe 50 between the space conversion unit 530 and the inspection target substrate 570, the probe 50 three-dimensionally moves in the lower guide hole 65 of the lower plate 70 and the upper guide hole 85 of the upper plate 90.

However, during the buckling of the elastic portion 10 of the probe 50, as shown in FIG. 2, the test head 100 moves two neighboring probes 50 so as to be close to each other, which increases the probability of contact between the two neighboring probes 50 using the anchor 5 of each individual probe 50. Contact between the two neighboring probes 50 mass-produces semiconductor chips that are physically good but electrically bad on the inspection target substrate 570.

The presence of the anchor 5 on the elastic portion 10 of the probe 50 deteriorates the buckling characteristics of the elastic portion 10, making the length of the elastic portion 10 greater than the length of the elastic portion 10 in the absence of the anchor 5. Therefore, an increase in the length of the elastic portion 10 increases the resistance of the probe 50, which degrades the electrical characteristics of the probe card 540.

### SUMMARY OF THE INVENTION

The present invention has been made in view of the above problems, and it is an object of the present invention to provide a probing head suitable for preventing contact between two neighboring probes and improving the electrical characteristics of a probe card when an elastic portion of a probe buckles in the state in which a probe card and an inspection target substrate are mounted on an electrical test device during an EDS process.

A probing head according to the present invention is configured such that, when an inspection target substrate is located under a space conversion unit of a probe card, the probing head is located between the space conversion unit and the inspection target substrate so as to be in contact with an electrical pad of the space conversion unit and a substrate pad of the inspection target substrate, wherein the probing head includes a probe located in the form of a pin from the inspection target substrate toward the space conversion unit, the probe having a displacement portion and an elastic portion located near the space conversion unit and the inspection target substrate, respectively, and a lower plate and an upper plate sequentially located in a longitudinal direction of the probe, the lower plate and the upper plate being configured to surround the displacement portion, the probe has an anchor protruding from the probe at the displacement portion, and the lower plate and the upper plate are located around the anchor so as to be spaced apart from each other on the probe.

The probe may be configured to be located at the lower plate and the upper plate in at least one and to move relative to the lower plate and the upper plate, when external force is applied to at least one of the space conversion unit and the inspection target substrate, so as to be electrically connected to the electric pad of the space conversion unit and the substrate pad of the inspection target substrate.

The displacement portion may be configured to have a straight shape on one side of the probe in the longitudinal direction of the probe and to have a straight shape around the anchor while having the anchor on the other side of the probe in the longitudinal direction of the probe.

The displacement portion may be configured to have a displacement hole portion located between the lower plate and the upper plate in the longitudinal direction of the probe, the displacement hole portion extending toward the lower plate and the upper plate, and to have the anchor around the displacement hole portion.

The displacement hole portion may have two displacement holes formed straight from the lower plate toward the upper plate, the two displacement holes being opened so as to have the same length in the longitudinal direction of the probe.

The anchor may be configured to have an inclined surface inclined relative to the probe toward the upper plate while facing the lower plate in the longitudinal direction of the probe, to have a curved surface facing the upper plate in the longitudinal direction of the probe, the curved surface being curved so as to be steeper than the inclined surface at the probe, and to have a flat surface between the inclined surface and the curved surface in the longitudinal direction of the probe.

The anchor may be configured to have an inclined surface inclined relative to the probe toward the upper plate while facing the lower plate in the longitudinal direction of the probe, to have a curved surface facing the upper plate in the longitudinal direction of the probe, the curved surface being curved so as to be steeper than the inclined surface at the probe, to have a flat surface between the inclined surface and the curved surface in the longitudinal direction of the probe, and to have an elastic hole formed in the anchor along the inclined surface, the flat surface, and the curved surface.

The anchor may be configured to have an inclined surface inclined relative to the probe toward the upper plate while facing the lower plate in the longitudinal direction of the probe, to have a curved surface facing the upper plate in the longitudinal direction of the probe, the curved surface being curved so as to be steeper than the inclined surface at the probe, to have a flat surface between the inclined surface and the curved surface in the longitudinal direction of the probe, to have an elastic hole formed in the anchor along the inclined surface, the flat surface, and the curved surface, and to allow the elastic hole to communicate with the displacement hole located around the anchor so as to be near the anchor.

The anchor may be configured to have a first curved surface facing the lower plate in the longitudinal direction of the probe, the first curved surface being curved so as to be erected at the probe, to have a second curved surface facing the upper plate in the longitudinal direction of the probe, the second curved surface being curved so as to be erected at the probe, and to have a flat surface between the first curved surface and the second curved surface in the longitudinal direction of the probe.

The anchor may be configured to have a first curved surface facing the lower plate in the longitudinal direction of the probe, the first curved surface being curved so as to be erected at the probe, to have a second curved surface facing the upper plate in the longitudinal direction of the probe, the second curved surface being curved so as to be erected at the probe, to have a flat surface between the first curved surface and the second curved surface in the longitudinal direction of the probe, and to have an elastic hole formed in the anchor along the first curved surface, the flat surface, and the second curved surface.

The anchor may be configured to have a first curved surface facing the lower plate in the longitudinal direction of the probe, the first curved surface being curved so as to be erected at the probe, to have a second curved surface facing the upper plate in the longitudinal direction of the probe, the second curved surface being curved so as to be erected at the probe, to have a flat surface between the first curved surface and the second curved surface in the longitudinal direction of the probe, to have an elastic hole formed in the anchor along the first curved surface, the flat surface, and the second curved surface, and to allow the elastic hole to communicate with the displacement hole located around the anchor so as to be near the anchor.

The anchor may be configured to have a first horizontal surface facing the lower plate in the longitudinal direction of the probe, the first horizontal surface being at an angle to the probe, to have a second horizontal surface facing the upper plate in the longitudinal direction of the probe, the second horizontal surface being at an angle to the probe, and to have a curved surface between the first horizontal surface and the second horizontal surface in the longitudinal direction of the probe.

The anchor may be configured to have a first horizontal surface facing the lower plate in the longitudinal direction of the probe, the first horizontal surface being at an angle to the probe, to have a second horizontal surface facing the upper plate in the longitudinal direction of the probe, the second horizontal surface being at an angle to the probe, to have a curved surface between the first horizontal surface and the second horizontal surface in the longitudinal direction of the probe, and to have an elastic hole formed in the anchor along the first horizontal surface, the curved surface, and the second horizontal surface.

The anchor may be configured to have a first horizontal surface facing the lower plate in the longitudinal direction of the probe, the first horizontal surface being at an angle to the probe, to have a second horizontal surface facing the upper plate in the longitudinal direction of the probe, the second horizontal surface being at an angle to the probe, to have a curved surface between the first horizontal surface and the second horizontal surface in the longitudinal direction of the probe, to have an elastic hole formed in the anchor along the first horizontal surface, the curved surface, and the second horizontal surface, and to allow the elastic hole to communicate with the displacement hole located around the anchor so as to be near the anchor.

The anchor may be configured to have an inclined surface inclined relative to the probe toward the upper plate while facing the lower plate in the longitudinal direction of the probe, to have a horizontal surface facing the upper plate in the longitudinal direction of the probe, the horizontal surface being at an angle to the probe, and to have a curved surface between the inclined surface and the horizontal surface in the longitudinal direction of the probe.

The anchor may be configured to have an inclined surface inclined relative to the probe toward the upper plate while facing the lower plate in the longitudinal direction of the probe, to have a horizontal surface facing the upper plate in the longitudinal direction of the probe, the horizontal surface being at an angle to the probe, to have a curved surface between the inclined surface and the horizontal surface in the longitudinal direction of the probe, and to have an elastic hole formed in the anchor along the inclined surface, the curved surface, and the horizontal surface.

The anchor may be configured to have an inclined surface inclined relative to the probe toward the upper plate while facing the lower plate in the longitudinal direction of the probe, to have a horizontal surface facing the upper plate in the longitudinal direction of the probe, the horizontal surface being at an angle to the probe, to have a curved surface between the inclined surface and the horizontal surface in the longitudinal direction of the probe, to have an elastic hole formed in the anchor along the inclined surface, the curved surface, and the horizontal surface, and to allow the elastic hole to communicate with the displacement hole located around the anchor so as to be near the anchor.

The anchor may be configured to have a first inclined surface inclined relative to the probe toward the upper plate while facing the lower plate in the longitudinal direction of the probe, to have a second inclined surface inclined relative to the probe toward the upper plate while facing the upper plate in the longitudinal direction of the probe, and to have a curved surface between the first inclined surface and the second inclined surface in the longitudinal direction of the probe.

The anchor may be configured to have a first inclined surface inclined relative to the probe toward the upper plate while facing the lower plate in the longitudinal direction of the probe, to have a second inclined surface inclined relative to the probe toward the upper plate while facing the upper plate in the longitudinal direction of the probe, to have a curved surface between the first inclined surface and the second inclined surface in the longitudinal direction of the probe, and to have an elastic hole formed in the anchor along the first inclined surface, the curved surface, and the second inclined surface.

The anchor may be configured to have a first inclined surface inclined relative to the probe toward the upper plate while facing the lower plate in the longitudinal direction of the probe, to have a second inclined surface inclined relative to the probe toward the upper plate while facing the upper plate in the longitudinal direction of the probe, to have a curved surface between the first inclined surface and the second inclined surface in the longitudinal direction of the probe, to have an elastic hole formed in the anchor along the first inclined surface, the curved surface, and the second inclined surface, and to allow the elastic hole to communicate with the displacement hole located around the anchor so as to be near the anchor.

The displacement hole portion may have two displacement holes formed straight from the lower plate toward the upper plate, the two displacement holes being opened so as to have different lengths in the longitudinal direction of the probe.

The anchor may be configured to have an inclined surface inclined relative to the probe toward the upper plate while facing the lower plate in the longitudinal direction of the probe, to have a curved surface facing the upper plate in the longitudinal direction of the probe, the curved surface being curved so as to be steeper than the inclined surface at the probe, and to have a flat surface between the inclined surface and the curved surface in the longitudinal direction of the probe.

The anchor may be configured to have an inclined surface inclined relative to the probe toward the upper plate while facing the lower plate in the longitudinal direction of the probe, to have a curved surface facing the upper plate in the longitudinal direction of the probe, the curved surface being curved so as to be steeper than the inclined surface at the probe, to have a flat surface between the inclined surface and the curved surface in the longitudinal direction of the probe, and to have an elastic hole formed in the anchor along the inclined surface, the flat surface, and the curved surface.

The anchor may be configured to have an inclined surface inclined relative to the probe toward the upper plate while facing the lower plate in the longitudinal direction of the probe, to have a curved surface facing the upper plate in the longitudinal direction of the probe, the curved surface being curved so as to be steeper than the inclined surface at the probe, to have a flat surface between the inclined surface and the curved surface in the longitudinal direction of the probe, to have an elastic hole formed in the anchor along the inclined surface, the flat surface, and the curved surface, and to allow the elastic hole to communicate with the displacement hole located around the anchor so as to be near the anchor.

The displacement hole portion may have a displacement hole located in a lower region, a middle region, and an upper region of the displacement hole portion, the displacement hole being opened so as to have a larger size in the middle region than in the lower region and the upper region in the longitudinal direction of the probe.

The anchor may be configured to have an inclined surface inclined relative to the probe toward the upper plate while facing the lower plate in the longitudinal direction of the probe, to have a curved surface facing the upper plate in the longitudinal direction of the probe, the curved surface being curved so as to be steeper than the inclined surface at the probe, and to have a flat surface between the inclined surface and the curved surface in the longitudinal direction of the probe.

The anchor may be configured to have an inclined surface inclined relative to the probe toward the upper plate while facing the lower plate in the longitudinal direction of the probe, to have a curved surface facing the upper plate in the longitudinal direction of the probe, the curved surface being curved so as to be steeper than the inclined surface at the probe, to have a flat surface between the inclined surface and the curved surface in the longitudinal direction of the probe, and to have an elastic hole formed in the anchor along the inclined surface, the flat surface, and the curved surface.

The anchor may be configured to have an inclined surface inclined relative to the probe toward the upper plate while facing the lower plate in the longitudinal direction of the probe, to have a curved surface facing the upper plate in the longitudinal direction of the probe, the curved surface being curved so as to be steeper than the inclined surface at the probe, to have a flat surface between the inclined surface and the curved surface in the longitudinal direction of the probe, to have an elastic hole formed in the anchor along the inclined surface, the flat surface, and the curved surface, and to allow the elastic hole to communicate with the displacement hole around the anchor.

### BRIEF DESCRIPTION OF THE DRAWINGS

FIG. 1 is a schematic view showing a conventional probe card;

FIG. 2 is a virtual view showing, by simulation, the positional relationship between a probe, a lower plate, and an upper plate during an EDS process in the probe card of FIG. 1;

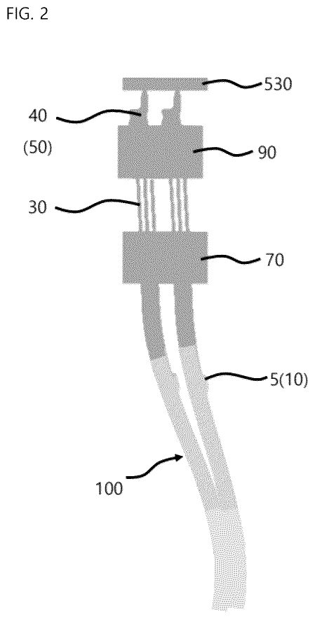

FIG. 3 is a schematic view showing a probe card according to the present invention;

FIG. 4 is a schematic view showing the shape of a probe in a probing head of FIG. 3;

FIG. 5 is a schematic view showing the probe located at a lower plate and an upper plate in the probing head of FIG. 3;

FIG. 6 is a schematic view showing a first modification of the probe of FIG. 5;

FIG. 7 is a schematic view showing a second modification of the probe of FIG. 5;

FIG. 8 is a schematic view showing a third modification of the probe of FIG. 5;

FIG. 9 is a schematic view showing a fourth modification of the probe of FIG. 5;

FIG. 10 is a schematic view showing a fifth modification of the probe of FIG. 5;

FIG. 11 is a schematic view showing a sixth modification of the probe of FIG. 5;

FIG. 12 is a schematic view showing a seventh modification of the probe of FIG. 5;

FIG. 13 is a schematic view showing an eighth modification of the probe of FIG. 5;

FIG. 14 is a schematic view showing a ninth modification of the probe of FIG. 5;

FIG. 15 is a schematic view showing a tenth modification of the probe of FIG. 5;

FIG. 16 is a schematic view showing an eleventh modification of the probe of FIG. 5;

FIG. 17 is a schematic view showing a twelfth modification of the probe of FIG. 5;

FIG. 18 is a schematic view showing a thirteenth modification of the probe of FIG. 5; and

FIG. 19 is a schematic view showing a fourteenth modification of the probe of FIG. 5.

### DETAILED DESCRIPTION OF THE PREFERRED EMBODIMENTS

Hereinafter, preferred embodiments of the present invention will be described in detail with reference to the accompanying drawings such that the present invention can be easily implemented by a person having ordinary skill in the art to which the present invention pertains.

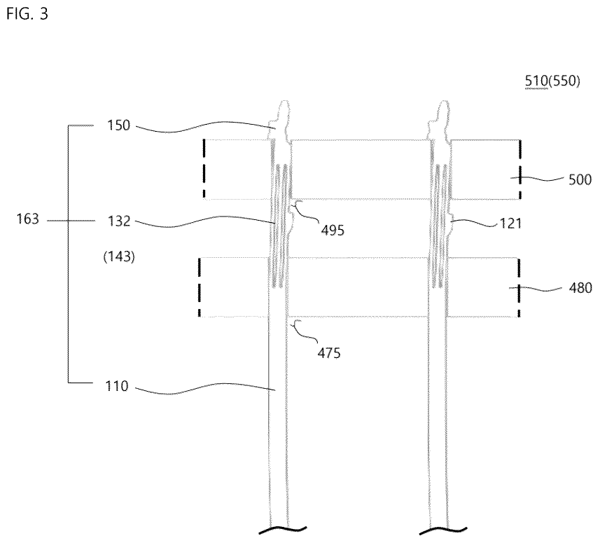

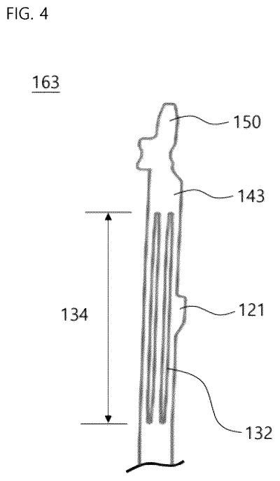

FIG. 3 is a schematic view showing a probe card according to the present invention, and FIG. 4 is a schematic view showing the shape of a probe in a probing head of FIG. 3.

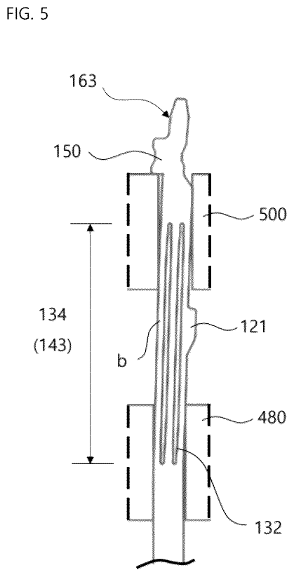

In addition, FIG. 5 is a schematic view showing the probe located at a lower plate and an upper plate in the probing head of FIG. 3.

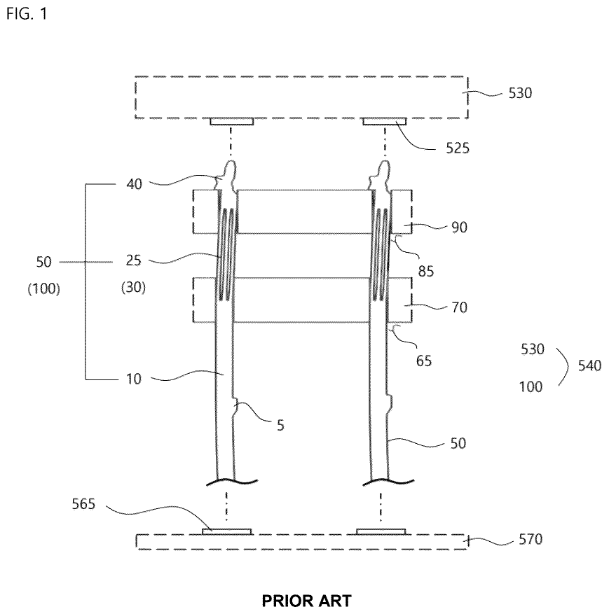

In this case, FIGS. 3 to 5 are described with reference to FIG. 1.

Referring to FIGS. 3 to 5, the probing head 510 according to the present invention is configured such that, when an inspection target substrate 570 is located under a space conversion unit 530 of the probe card 550, considering FIGS. 1 and 3, the probing head is located between the space conversion unit 530 and the inspection target substrate 570 so as to be in contact with an electrical pad 525 of the space conversion unit 530 and a substrate pad 565 of the inspection target substrate 570.

To this end, considering FIGS. 3 and 4, the probing head 510 includes a probe 163 located in the form of a pin from the inspection target substrate 570 toward the space conversion unit 530, the probe having a displacement portion 143 and an elastic portion 110 located near the space conversion unit 530 and the inspection target substrate 570, respectively, and a lower plate 480 and an upper plate 500 sequentially located in a longitudinal direction of the probe 163, the lower plate and the upper plate being configured to surround the displacement portion 143.

Here, the probe 163 has an anchor 121 that protrudes from the probe 163 at the displacement portion 143 in FIGS. 3 to 5. The lower plate 480 and the upper plate 500 are located around the anchor 121 so as to be spaced apart from each other on the probe 163 considering FIGS. 3 and 5. The probe 163 is located at the lower plate 480 and the upper plate 500 in at least one in FIG. 3, and when external force is applied to at least one of the space conversion unit 530 and the inspection target substrate 570, the probe moves relative to the lower plate 480 and the upper plate 500 and is electrically connected to the electric pad 525 of the space conversion unit 530 and the substrate pad 565 of the inspection target substrate 570.

That is, the probe 163 comes into contact with the electrical pad 525 of the space conversion unit 530 through a probing upper tip 150, and comes into contact with the substrate pad 565 of the inspection target substrate 570 through a probing lower tip (not shown). Considering FIGS. 3 to 5, the displacement portion 143 has a straight shape on one side of the probe 163 in the longitudinal direction of the probe 163, and has a straight shape around the anchor 121 while having the anchor 121 on the other side of the probe 163 in the longitudinal direction of the probe 163.

Considering FIGS. 4 and 5, the displacement portion 143 has a displacement hole portion 143 located between the lower plate 480 and the upper plate 500 in the longitudinal direction of the probe 163, the displacement hole portion extending toward the lower plate 480 and the upper plate 500, and has the anchor 121 around the displacement hole portion 143.

In FIGS. 4 and 5, the displacement hole portion 143 has two displacement holes 132 that are formed straight from the lower plate 480 toward the upper plate 500 and that are opened so as to have the same length in the longitudinal direction of the probe 163. The displacement hole portion 143 has a plurality of beams b that are located between two displacement holes 132 and surround two displacement holes 132, and forms elastic bodies that are connected in parallel using the plurality of beams b. The parallel synthesis of elastic moduli of the elastic bodies may make it difficult to displace the displacement portion 143 in proportion to the increase in the number of individual beams b, from a physics perspective.

Considering FIGS. 3 to 5, the anchor 121 has an inclined surface inclined relative to the probe 143 toward the upper plate 500 while facing the lower plate 480 in the longitudinal direction of the probe 163, has a curved surface that faces the upper plate 500 in the longitudinal direction of the probe 163 and is curved so as to be steeper than the inclined surface at the probe 163, and has a flat surface between the inclined surface and the curved surface in the longitudinal direction of the probe 163.

Meanwhile, the probe 163 may replace the probe 50 of FIG. 1.

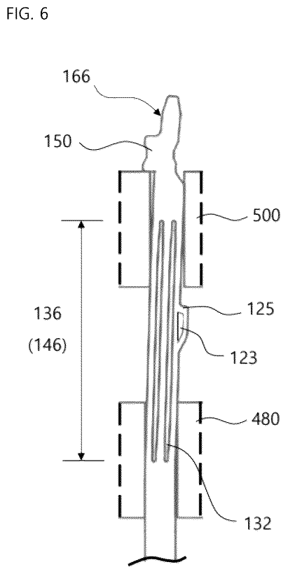

FIG. 6 is a schematic view showing a first modification of the probe of FIG. 5.

Referring to FIG. 6, the probe 166 according to the first modification of the present invention is similar to the probe 163 of FIG. 5, but an anchor 125 of the probe 166 has a different shape from the anchor 121 of the probe 163 of FIG. 5.

Therefore, in order to highlight the invention, a displacement portion 146, a displacement hole portion 136, and the anchor 125 in FIG. 6 are denoted by different reference numerals from the displacement portion 143, the displacement hole portion 134, and the anchor 121 in FIG. 5.

More specifically, the anchor 125 has an inclined surface inclined relative to the probe 166 toward the upper plate 500 (FIG. 5) while facing the lower plate 480 (FIG. 5) in the longitudinal direction of the probe 166, has a curved surface that faces the upper plate 500 in the longitudinal direction of the probe 166 and is curved so as to be steeper than the inclined surface at the probe 166, has a flat surface between the inclined surface and the curved surface in the longitudinal direction of the probe 166, and has an elastic hole 123 formed in the anchor 125 along the inclined surface, the flat surface, and the curved surface.

At this time, the anchor 125 forms elastic bodies connected in parallel along an angular border between the inclined surface, the flat surface, and the curved surface along with an inner surface of the elastic hole 123. The parallel synthesis of elastic moduli of the elastic bodies may make it difficult to deform the anchor 125 in proportion to the increase in the opening area of the elastic hole 123, from a physics perspective.

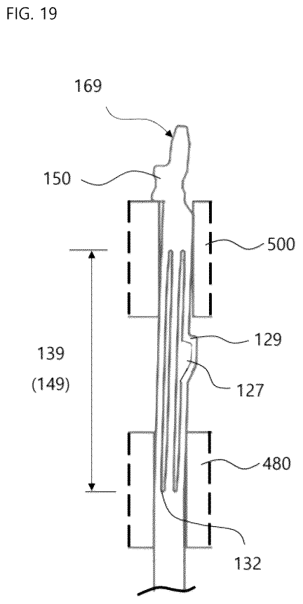

FIG. 19 is a schematic view showing a fourteenth modification of the probe of FIG. 5.

Referring to FIG. 19, the probe 169 according to the fourteenth modification of the present invention is similar to the probe 163 of FIG. 5, but an anchor 129 of the probe 169 has a different shape from the anchor 121 of the probe 163 of FIG. 5.

Therefore, in order to highlight the invention, a displacement portion 149, a displacement hole portion 139, and the anchor 129 in FIG. 19 are denoted by different reference numerals from the displacement portion 143, the displacement hole portion 134, and the anchor 121 in FIG. 5.

More specifically, the anchor 129 has an inclined surface inclined relative to the probe 169 toward the upper plate 500 while facing the lower plate 480 in the longitudinal direction of the probe 169, has a curved surface that faces the upper plate 500 in the longitudinal direction of the probe 169 and is curved so as to be steeper than the inclined surface at the probe 169, has a flat surface between the inclined surface and the curved surface in the longitudinal direction of the probe 169, has an elastic hole 127 formed in the anchor 129 along the inclined surface, the flat surface, and the curved surface, and allows the elastic hole 127 to communicate with a displacement hole 132 located around the anchor 129 so as to be near the anchor 129.

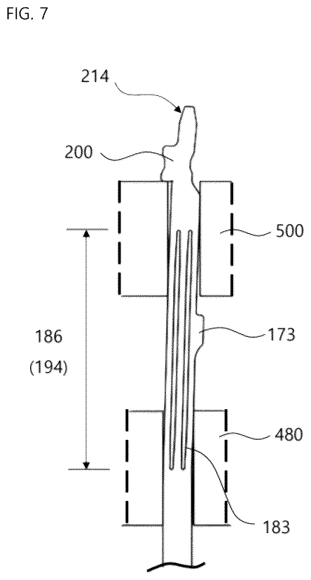

FIG. 7 is a schematic view showing second modification of the probe of FIG. 5.

Referring to FIG. 7, the probe 214 according to the second modification of the present invention is similar to the probe 163 of FIG. 5, but an anchor 173 of the probe 214 has a different shape from the anchor 121 of the probe 163 of FIG. 5.

Therefore, in order to highlight the invention, a probing upper tip 200, a displacement portion 194, a displacement hole portion 186, a displacement hole 183, and the anchor 173 in FIG. 7 are denoted by different reference from the probing upper tip 150, the displacement numerals portion 143, the displacement hole portion 134, the displacement hole 132, and the anchor 121 in FIG. 5.

More specifically, the anchor 173 has a first curved surface that faces the lower plate 480 in the longitudinal direction of the probe 214 and is curved so as to be erected at the probe 214, has a second curved surface that faces the upper plate 500 in the longitudinal direction of the probe 214 and is curved so as to be erected at the probe 214, and has a flat surface between the first curved surface and the second curved surface in the longitudinal direction of the probe 214.

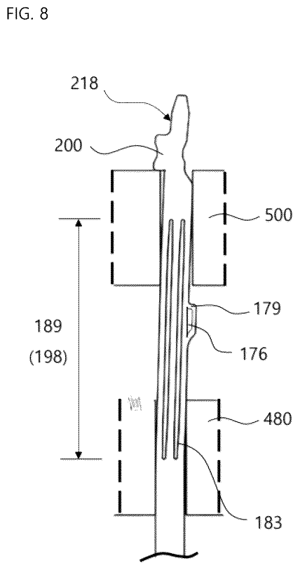

FIG. 8 is a schematic view showing a third modification of the probe of FIG. 5.

Referring to FIG. 8, the probe 218 according to the third modification of the present invention is similar to the probe 163 of FIG. 5, but an anchor 179 of the probe 218 has a different shape from the anchor 121 of the probe 163 of FIG. 5.

Here, in order to highlight the invention, a displacement portion 198, a displacement hole portion 189, and the anchor 179 in FIG. 8 are denoted by different reference numerals from the displacement portion 194, the displacement hole portion 186, and the anchor 173 in FIG. 7.

More specifically, the anchor 179 has a first curved surface that faces the lower plate 480 in the longitudinal direction of the probe 218 and is curved so as to be erected at the probe 218, has a second curved surface that faces the upper plate 500 in the longitudinal direction of the probe 218 and is curved so as to be erected at the probe 218, has a flat surface between the first curved surface and the second curved surface in the longitudinal direction of the probe 218, and has an elastic hole 176 formed in the anchor 179 along the first curved surface, the flat surface, and the second curved surface.

Meanwhile, although not shown in the figure, a modification of the probe 218 has a shape similar to the shape of the probe 218, and may allow the elastic hole 176 to communicate with a displacement hole 183 located around the anchor 179 so as to be near the anchor 179, similarly to FIG. 19.

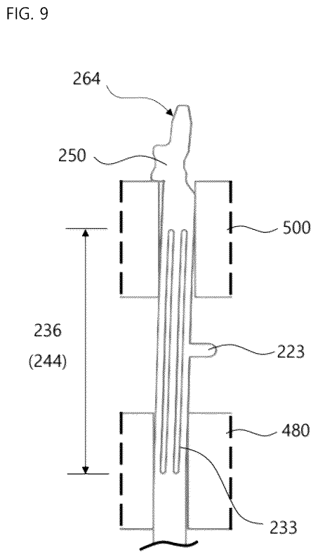

FIG. 9 is a schematic view showing a fourth modification of the probe of FIG. 5.

Referring to FIG. 9, the probe 264 according to the fourth modification of the present invention is similar to the probe 163 of FIG. 5, but an anchor 223 of the probe 264 has a different shape from the anchor 121 of the probe 163 of FIG. 5.

Therefore, in order to highlight the invention, a probing upper tip 250, a displacement portion 244, a displacement hole portion 236, a displacement hole 233, and the anchor 223 in FIG. 9 are denoted by different reference numerals from the probing upper tip 150, the displacement portion 143, the displacement hole portion 134, the displacement hole 132, and the anchor 121 in FIG. 5.

More specifically, the anchor 223 has a first horizontal surface that faces the lower plate 480 in the longitudinal direction of the probe 264 and is at an angle to the probe 264, has a second horizontal surface that faces the upper plate 500 in the longitudinal direction of the probe 264 and is at an angle to the probe 264, and has a curved surface between the first horizontal surface and the second horizontal surface in the longitudinal direction of the probe 264.

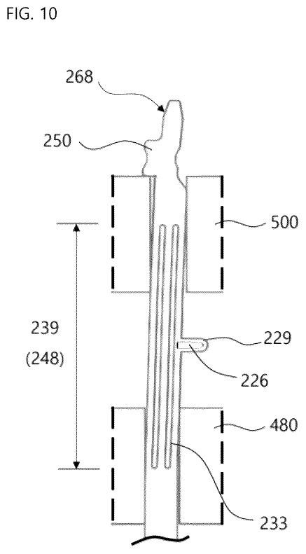

FIG. 10 is a schematic view showing a fifth modification example of the probe of FIG. 5.

Referring to FIG. 10, the probe 268 according to the fifth modification of the present invention is similar to the probe 163 of FIG. 5, but an anchor 229 of the probe 268 has a different shape from the anchor 121 of the probe 163 of FIG. 5.

Here, in order r to highlight the invention, a displacement portion 248, a displacement hole portion 239, and the anchor 229 in FIG. 10 are denoted by different reference numerals from the displacement portion 244, the displacement hole portion 236, and the anchor 223 in FIG. 9.

More specifically, the anchor 229 has first horizontal surface that faces the lower plate 480 in the longitudinal direction of the probe 268 and is at an angle to the probe 268, has a second horizontal surface that faces the upper plate 500 in the longitudinal direction of the probe 268 and is at an angle to the probe 268, has a curved surface between the first horizontal surface and the second horizontal surface in the longitudinal direction of the probe 268, and has an elastic hole 226 formed in the anchor 229 along the first horizontal surface, the curved surface, and the second horizontal surface.

Meanwhile, although not shown in the figure, a modification of the probe 268 has a shape similar to the shape of the probe 268, and may allow the elastic hole 226 to communicate with a displacement hole 233 located around the anchor 229 so as to be near the anchor 229, similarly to FIG. 19.

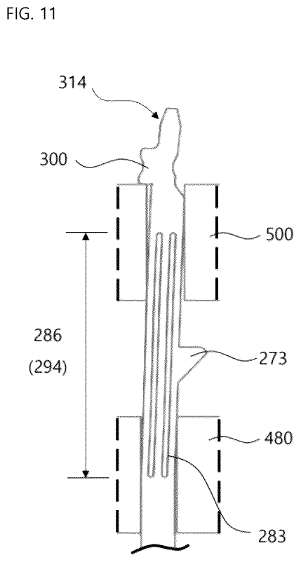

FIG. 11 is a schematic view showing a sixth modification of the probe of FIG. 5.

Referring to FIG. 11, the probe 314 according to the sixth modification of the present invention is similar to the probe 163 of FIG. 5, but an anchor 273 of the probe 314 has a different shape from the anchor 121 of the probe 163 of FIG. 5.

Therefore, in order to highlight the invention, a probing upper tip 300, a displacement portion 294, a displacement hole portion 286, a displacement hole 283, and the anchor 273 in FIG. 11 are denoted by different reference numerals from the probing upper tip 150, the displacement portion 143, the displacement hole portion 134, the displacement hole 132, and the anchor 121 in FIG. 5.

More specifically, the anchor 273 has an inclined surface inclined relative to the probe 314 toward the upper plate 500 while facing the lower plate 480 in the longitudinal direction of the probe 314, has a horizontal surface that faces the upper plate 500 in the longitudinal direction of the probe 314 and is at an angle to the probe 314, and has a curved surface between the inclined surface and the horizontal surface in the longitudinal direction of the probe 314.

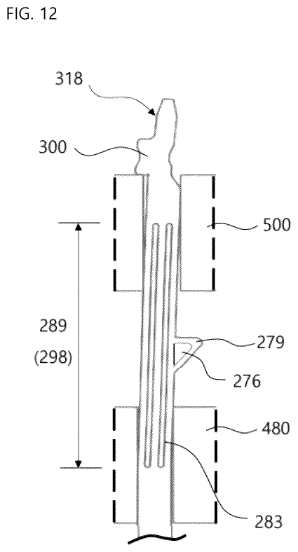

FIG. 12 is a schematic view showing a seventh modification of the probe of FIG. 5.

Referring to FIG. 12, the probe 318 according to the seventh modification of the present invention is similar to the probe 163 of FIG. 5, but an anchor 279 of the probe 318 has a different shape from the anchor 121 of the probe 163 of FIG. 5.

Here, in order to highlight the invention, a displacement portion 298, a displacement hole portion 289, and the anchor 279 in FIG. 12 are denoted by different reference numerals from the displacement portion 294, the displacement hole portion 286, and the anchor 273 in FIG. 11.

More specifically, the anchor 279 has an inclined surface inclined relative to the probe 318 toward the upper plate 500 while facing the lower plate 480 in the longitudinal direction of the probe 318, has a horizontal surface that faces the upper plate 500 in the longitudinal direction of the probe 318 and is at an angle to the probe 318, has a curved surface between the inclined surface and the horizontal surface in the longitudinal direction of the probe 318, and has an elastic hole 276 formed in the anchor 279 along the inclined surface, the curved surface, and the horizontal surface.

Meanwhile, although not shown in the figure, a modification of the probe 318 has a shape similar to the shape of the probe 318, and may allow the elastic hole 276 to communicate with a displacement hole 283 located around the anchor 279 so as to be near the anchor 279, similarly to FIG. 19.

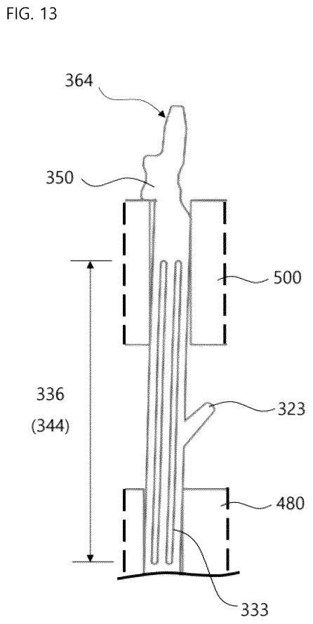

FIG. 13 is a schematic view showing an eighth modification of the probe of FIG. 5.

Referring to FIG. 13, the probe 364 according to the eighth modification of the present invention is similar to the probe 163 of FIG. 5, but an anchor 323 of the probe 364 has a different shape from the anchor 121 of the probe 163 of FIG. 5.

Therefore, in order to highlight the invention, a probing upper tip 350, a displacement portion 344, a displacement hole portion 336, a displacement hole 333, and the anchor 323 in FIG. 13 are denoted by different reference numerals from the probing upper tip 150, the displacement portion 143, the displacement hole portion 134, the displacement hole 132, and the anchor 121 in FIG. 5.

More specifically, the anchor has a first inclined surface inclined relative to the probe 364 toward the upper plate 500 while facing the lower plate 480 in the longitudinal direction of the probe 364, has a second inclined surface inclined relative to the probe 364 toward the upper plate 500 while facing the upper plate 500 in the longitudinal direction of the probe 364, and has a curved surface between the first inclined surface and the second inclined surface in the longitudinal direction of the probe 364.

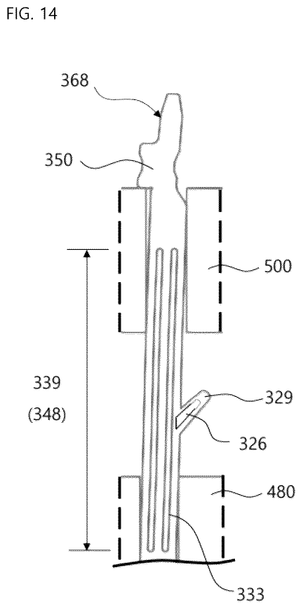

FIG. 14 is a schematic view showing a ninth modification of the probe of FIG. 5.

Referring to FIG. 14, the probe 368 according to the ninth modification of the present invention is similar to the probe 163 of FIG. 5, but an anchor 329 of the probe 368 has a different shape from the anchor 121 of the probe 163 of FIG. 5.

Here, in order to highlight the invention, a displacement portion 348, a displacement hole portion 339, and the anchor 329 in FIG. 14 are denoted by different reference numerals from the displacement portion 344, the displacement hole portion 336, and the anchor 323 in FIG. 13.

More specifically, the anchor 329 has a first inclined surface inclined relative to the probe 368 toward the upper plate 500 while facing the lower plate 480 in the longitudinal direction of the probe 368, has a second inclined surface inclined relative to the probe 368 toward the upper plate 500 while facing the upper plate 500 in the longitudinal direction of the probe 368, has a curved surface between the first inclined surface and the second inclined surface in the longitudinal direction of the probe 368, and has an elastic hole 326 formed in the anchor 329 along the first inclined surface, the curved surface, and the second inclined surface.

Meanwhile, although t shown in the figure, a modification of the probe 368 has a shape similar to the shape of the probe 368, and may allow the elastic hole 326 to communicate with a displacement hole 333 located around the anchor 329 so as to be near the anchor 329, similarly to FIG. 19.

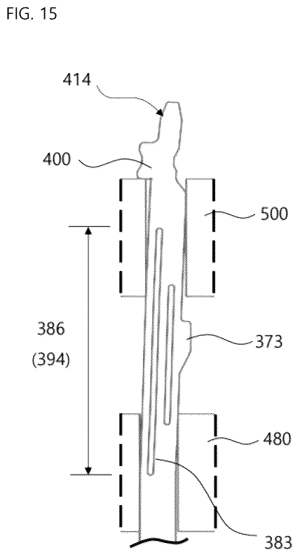

FIG. 15 is a schematic view showing a tenth modification of the probe of FIG. 5.

Referring to FIG. 15, the probe 414 according to the tenth modification of the present invention is similar to the probe 163 of FIG. 5, but the positional relationship between a displacement hole portion 386 and an anchor 373 at a displacement portion 394 of the probe 414 is different from the positional relationship between the displacement hole portion 134 and the anchor 121 at the displacement portion 143 of the probe 163 of FIG. 5.

Therefore, in order to highlight the invention, a probing upper tip 400, the displacement portion 394, the displacement hole portion 386, a displacement hole 383, and the anchor FIG. 15 are denoted by different reference numerals from the probing upper tip 150, the displacement portion 143, the displacement hole portion 134, the displacement hole 132, and the anchor 121 in FIG. 5.

More specifically, the displacement hole portion 386 has two displacement holes 383 that are formed straight from the lower plate 480 toward the upper plate 500 and that are opened so as to have different lengths in the longitudinal direction of the probe 414.

In addition, the anchor 373 has an inclined surface inclined relative to the probe 414 toward the upper plate 500 while facing the lower plate 480 in the longitudinal direction of the probe 414, has a curved surface that faces the upper plate 500 in the longitudinal direction of the probe 414 and is curved so as to be steeper than the inclined surface at the probe 414, and has a flat surface between the inclined surface and the curved surface in the longitudinal direction of the probe 414.

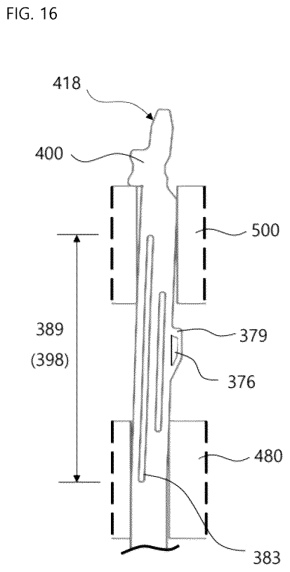

FIG. 16 is a schematic view showing an eleventh modification of the probe of FIG. 5.

Referring to FIG. 16, the probe 418 according to the eleventh modification of the present invention is similar to the probe 163 of FIG. 5, but the positional relationship between a displacement hole portion 389 and an anchor 379 at a displacement portion 398 of the probe 418 is different from the positional relationship between the displacement hole portion 134 and the anchor 121 at the displacement portion 143 of the probe 163 of FIG. 5.

Here, in order to highlight the invention, displacement portion 398, the displacement hole portion 389, and the anchor 379 in FIG. 16 are denoted by different reference numerals from the displacement portion 394, the displacement hole portion 386, and the anchor 373 in FIG. 15.

More specifically, the displacement hole portion 389 has two displacement holes 383 that are formed straight from the lower plate 480 toward the upper plate 500 and that are opened so as to have different lengths in the longitudinal direction of the probe 418.

In addition, the anchor 379 has an inclined surface inclined relative to the probe 418 toward the upper plate 500 while facing the lower plate 480 in the longitudinal direction of the probe 418, has a curved surface that faces the upper plate 500 in the longitudinal direction of the probe 418 and is curved so as to be steeper than the inclined surface at the probe 418, has a flat surface between the inclined surface and the curved surface in the longitudinal direction of the probe 418, and has an elastic hole 376 formed in the anchor 379 along the inclined surface, the flat surface, and the curved surface.

Meanwhile, although shown in the figure, a modification of the probe 418 has a shape similar to the shape of the probe 418, and may allow the elastic hole 376 to communicate with the displacement hole 383 located around the anchor 379 so as to be near the anchor 379, similarly to FIG. 19.

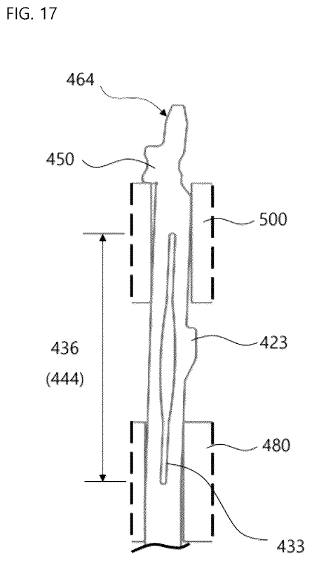

FIG. 17 is a schematic view showing a twelfth modification of the probe of FIG. 5.

Referring to FIG. 17, the probe 464 according to the twelfth modification of the present invention is similar to the probe 163 of FIG. 5, but the positional relationship between a displacement hole portion 436 and an anchor 423 at a displacement portion 444 of the probe 464 is different from the positional relationship between the displacement hole portion 134 and the anchor 121 at the displacement portion 143 of the probe 163 of FIG. 5.

Therefore, in order to highlight the invention, a probing upper tip 450, the displacement portion 444, the displacement hole portion 436, a displacement hole 433, and the anchor 423 in FIG. 17 are denoted by different reference numerals from the probing upper tip 150, the displacement portion 143, the displacement hole portion 134, the displacement hole 132, and the anchor 121 in FIG. 5.

More specifically, the displacement hole portion 436 has a displacement hole 433 that is located in a lower region, a middle region, and an upper region of the displacement hole portion 436 and is opened so as to have a larger size in the middle region than in the lower region and the upper region in the longitudinal direction of the probe 464.

In addition, the anchor 423 has an inclined surface inclined relative to the probe 464 toward the upper plate 500 while facing the lower plate 480 in the longitudinal direction of the probe 464, has a curved surface that faces the upper plate 500 in the longitudinal direction of the probe 464 and is curved so as to be steeper than the inclined surface at the probe 464, and has a flat surface between the inclined surface and the curved surface in the longitudinal direction of the probe 464.

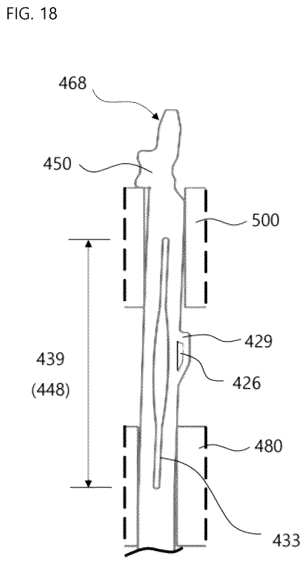

FIG. 18 is a schematic view showing a thirteenth modification of the probe of FIG. 5.

Referring to FIG. 18, the probe 468 according to the thirteenth modification of the present invention is similar to the probe 163 of FIG. 5, but the positional relationship between a displacement hole portion 439 and an anchor 429 at a displacement portion 448 of the probe 468 is different from the positional relationship between the displacement hole portion 134 and the anchor 121 at the displacement portion 143 of the probe 163 of FIG. 5.

Here, in order to highlight the invention, the displacement portion 448, the displacement hole portion 439, and the anchor 429 in FIG. 18 are denoted by different reference numerals from the displacement portion 444, the displacement hole portion 436, and the anchor 423 in FIG. 17.

More specifically, the displacement hole portion 439 has a displacement hole 433 that is located in a lower region, a middle region, and an upper region of the displacement hole portion 439 and is opened so as to have a larger size in the middle region than in the lower region and the upper region in the longitudinal direction of the probe 468.

In addition, the anchor 429 has an inclined surface inclined relative to the probe 468 toward the upper plate 500 while facing the lower plate 480 in the longitudinal direction of the probe 468, has a curved surface that faces the upper plate 500 in the longitudinal direction of the probe 468 and is curved so as to be steeper than the inclined surface at the probe 468, has a flat surface between the inclined surface and the curved surface in the longitudinal direction of the probe 468, and has an elastic hole 426 formed in the anchor 429 along the inclined surface, the flat surface, and the curved surface.

As is apparent from the above description, a probing head according to the present invention is configured such that, when an inspection target substrate is located under a space conversion unit of a probe card, the probing head is located between the space conversion unit and the inspection target substrate so as to be in contact with an electrical pad of the space conversion unit and a substrate pad of the inspection target substrate.

The probing head includes a probe having an elastic portion and a displacement portion sequentially located between the inspection target substrate and the space conversion unit and lower and upper plates that are sequentially located in a longitudinal direction of the probe and surround the displacement portion.

No anchor is provided at the elastic portion, two displacement holes are formed in the displacement portion, an anchor is provided at the displacement portion, and the lower and upper plates are located around the anchor at the probe.

Consequently, when the elastic portion of the probe buckles in the state in which the probe card and the inspection target substrate are mounted on an electrical test device during an EDS process, it is possible to prevent contact between two neighboring probes due to the displacement of the anchor from the elastic portion to the displacement portion and to reduce the length of the elastic portion while improving the buckling characteristics of the elastic portion due to the absence of the anchor at the elastic portion, whereby it is possible to improve the electrical characteristics of the probe card.

What is claimed is:

1. A probing head configured such that, when an inspection target substrate is located under a space conversion unit of a probe card, the probing head is located between the space conversion unit and the inspection target substrate so as to be in contact with an electrical pad of the space conversion unit and a substrate pad of the inspection target substrate, the probing head comprising:
a probe located in the form of a pin from the inspection substrate toward the space conversion unit, the probe having a displacement portion and an elastic portion located near the space conversion unit and the inspection target substrate, respectively; and
a lower plate and an upper plate sequentially located in a longitudinal direction of the probe, the lower plate and the upper plate being configured to surround the displacement portion, wherein
the probe has an anchor protruding from the probe at the displacement portion, and
the lower plate and the upper plate are located around the anchor so as to be spaced apart from each other on the probe.

2. The probing head according to claim 1, wherein the probe is configured:
to be located at the lower plate and the upper plate in at least one; and
to move relative to the lower plate and the upper plate, when external force is applied to at least one of the space conversion unit and the inspection target substrate, so as to be electrically connected to the electric pad of the space conversion unit and the substrate pad of the inspection target substrate.

3. The probing head according to claim 1, wherein the displacement portion is configured:
to have a straight shape on one side of the probe in the longitudinal direction of the probe; and
to have a straight shape around the anchor while having the anchor on the other side of the probe in the longitudinal direction of the probe.

4. The probing head according to claim 1, wherein the displacement portion is configured:
to have a displacement hole portion located between the lower plate and the upper plate in the longitudinal direction of the probe, the displacement hole portion extending toward the lower plate and the upper plate; and
to have the anchor around the displacement hole portion.

5. The probing head according to claim 4, wherein the displacement hole portion has two displacement holes formed straight from the lower plate toward the upper plate, the two displacement holes being opened so as to have the same length in the longitudinal direction of the probe.

6. The probing head according to claim 5, wherein the anchor is configured:
to have an inclined surface inclined relative to the probe toward the upper plate while facing the lower plate in the longitudinal direction of the probe;
to have a curved surface facing the upper plate in the longitudinal direction of the probe, the curved surface being curved so as to be steeper than the inclined surface at the probe; and
to have a flat surface between the inclined surface and the curved surface in the longitudinal direction of the probe.

7. The probing head according to claim 5, wherein the anchor is configured:
to have an inclined surface inclined relative to the probe toward the upper plate while facing the lower plate in the longitudinal direction of the probe;
to have a curved surface facing the upper plate in the longitudinal direction of the probe, the curved surface being curved so as to be steeper than the inclined surface at the probe;
to have a flat surface between the inclined surface and the curved surface in the longitudinal direction of the probe; and
to have an elastic hole formed in the anchor along the inclined surface, the flat surface, and the curved surface.

8. The probing head according to claim 5, wherein the anchor is configured:
to have an inclined surface inclined relative to the probe toward the upper plate while facing the lower plate in the longitudinal direction of the probe;
to have a curved surface facing the upper plate in the longitudinal direction of the probe, the curved surface being curved so as to be steeper than the inclined surface at the probe;
to have a flat surface between the inclined surface and the curved surface in the longitudinal direction of the probe;
to have an elastic hole formed in the anchor along the inclined surface, the flat surface, and the curved surface; and
to allow the elastic hole to communicate with the displacement hole located around the anchor so as to be near the anchor.

9. The probing head according to claim 5, wherein the anchor is configured:
to have a first curved surface facing the lower plate in the longitudinal direction of the probe, the first curved surface being so as to be erected at the probe;
to have a second curved surface facing the upper plate in the longitudinal direction of the probe, the second curved surface being curved so as to be erected at the probe; and
to have a flat surface between the first curved surface and the second curved surface in the longitudinal direction of the probe.

10. The probing head according to claim 5, wherein the anchor is configured:
to have a first curved surface facing the lower plate in the longitudinal direction of the probe, the first curved surface being curved so as to be erected at the probe;
to have a second curved surface facing the upper plate in the longitudinal direction of the probe, the second curved surface being curved so as to be erected at the probe; to have a flat surface between the first curved surface and the second curved surface in the longitudinal direction of the probe; and
to have an elastic hole formed in the anchor along the first curved surface, the flat surface, and the second curved surface.

11. The probing head according to claim 5, wherein the anchor is configured:
to have a first horizontal surface facing the lower plate in the longitudinal direction of the probe, the first horizontal surface being at an angle to the probe;
to have a second horizontal surface facing the upper plate in the longitudinal direction of the probe, the second horizontal surface being at an angle to the probe; and
to have a curved surface between the first horizontal surface and the second horizontal surface in the longitudinal direction of the probe.

12. The probing head according to claim 5, wherein the anchor is configured:
to have a first horizontal surface facing the lower plate in the longitudinal direction of the probe, the first horizontal surface being at an angle to the probe;
to have a second horizontal surface facing the upper plate in the longitudinal direction of the probe, the second horizontal surface being at an angle to the probe;
to have a curved surface between the first horizontal surface and the second horizontal surface in the longitudinal direction of the probe; and
to have an elastic hole formed in the anchor along the first horizontal surface, the curved surface, and the second horizontal surface.

13. The probing head according to claim 5, wherein the anchor is configured:
to have an inclined surface inclined relative to the probe toward the upper plate while facing the lower plate in the longitudinal direction of the probe;
to have a horizontal surface facing the upper plate in the longitudinal direction of the probe, the horizontal surface being at an angle to the probe; and
to have a curved surface between the inclined surface and the horizontal surface in the longitudinal direction of the probe.

14. The probing head according to claim 5, wherein the anchor is configured:
to have an inclined surface inclined relative to the probe toward the upper plate while facing the lower plate in the longitudinal direction of the probe;
to have a horizontal surface facing the upper plate in the longitudinal direction of the probe, the horizontal surface being at an angle to the probe;
to have a curved surface between the inclined surface and the horizontal surface in the longitudinal direction of the probe; and
to have an elastic hole formed in the anchor along the inclined surface, the curved surface, and the horizontal surface.

15. The probing head according to claim 5, wherein the anchor is configured:
to have a first inclined surface inclined relative to the probe toward the upper plate while facing the lower plate in the longitudinal direction of the probe;
to have a second inclined surface inclined relative to the probe toward the upper plate while facing the upper plate in the longitudinal direction of the probe; and
to have a curved surface between the first inclined surface and the second inclined surface in the longitudinal direction of the probe.

16. The probing head according to claim 5, wherein the anchor is configured:
to have a first inclined surface inclined relative to the probe toward the upper plate while facing the lower plate in the longitudinal direction of the probe;
to have a second inclined surface inclined relative to the probe toward the upper plate while facing the upper plate in the longitudinal direction of the probe;
to have a curved surface between the first inclined surface and the second inclined surface in the longitudinal direction of the probe; and
to have an elastic hole formed in the anchor along the first inclined surface, the curved surface, and the second inclined surface.

17. The probing head according to claim 4, wherein the displacement hole portion has two displacement holes formed straight from the lower plate toward the upper plate, the two displacement holes being opened so as to have different lengths in the longitudinal direction of the probe.

18. The probing head according to claim 17, wherein the anchor is configured:
to have an inclined surface inclined relative to the probe toward the upper plate while facing the lower plate in the longitudinal direction of the probe;
to have a curved surface facing the upper plate in the longitudinal direction of the probe, the curved surface being curved so as to be steeper than the inclined surface at the probe; and
to have a flat surface between the inclined surface and the curved surface in the longitudinal direction of the probe.

19. The probing head according to claim 4, wherein the displacement hole portion has a displacement hole located in a lower region, a middle region, and an upper region of the displacement hole portion, the displacement hole being opened so as to have a larger size in the middle region than in the lower region and the upper region in the longitudinal direction of the probe.

20. The probing head according to claim 19, wherein the anchor is configured:
to have an inclined surface inclined relative to the probe toward the upper plate while facing the lower plate in the longitudinal direction of the probe;
to have a curved surface facing the upper plate in the longitudinal direction of the probe, the curved surface being curved so as to be steeper than the inclined surface at the probe; and
to have a flat surface between the inclined surface and the curved surface in the longitudinal direction of the probe.
